(19) United States
(12) Patent Application Publication
(10) Pub. No.: US 2025/0125580 A1
(43) Pub. Date: Apr. 17, 2025

(54) DUAL REDUNDANCY HIGH RELIABILITY LASER DIODE LIGHTING PLATFORM

(71) Applicant: M3 Innovation, LLC, Syracuse, NY (US)

(72) Inventors: Christopher D. Nolan, Camillus, NY (US); Joseph R. Casper, Baldwinsville, NY (US)

(73) Assignee: M3 Innovation, LLC, Syracuse, NY (US)

(21) Appl. No.: 18/913,748

(22) Filed: Oct. 11, 2024

Related U.S. Application Data
(60) Provisional application No. 63/589,584, filed on Oct. 11, 2023.

(51) Int. Cl. H01S 5/042; H01S 5/024; H01S 5/40

(52) U.S. Cl. CPC H01S 5/042; H01S 5/02423; H01S 5/4075

(57) ABSTRACT

An illumination system, having a luminaire having an illumination source positioned in a housing and having a plurality of columns of laser diodes, each column of laser diodes is coupled to one of a corresponding plurality of independent electrical power pathways; a power supply enclosure independent from and positioned separately from the luminaire and enclosing a plurality of laser diode drivers, each interconnected to a corresponding one of the plurality of independent electrical power pathways so that each of the plurality of laser diode drivers can output an amount of power to each of the plurality of columns of laser diodes; and a microprocessor positioned in the power supply enclosure and coupled to the plurality of laser diode drivers to set an amount of power that is output from each of the plurality of laser diode drivers to the corresponding one of the plurality of columns of laser diodes.

### CROSS-REFERENCE TO RELATED APPLICATIONS

This application claims priority under 35 U.S.C. § 119 to U.S. Provisional Application No. 63/589,584, filed Oct. 11, 2023, which is herein incorporated by reference in its entirety.

### BACKGROUND OF THE INVENTION

### Technical field

The present invention relates to sports lighting systems and, more specifically, to a more specifically, to a laser diode lighting system having redundancy to provide improved reliability.

### Background Information

Conventional sports lighting systems rely on individual luminaires that are mounted along the cross-arms of a support pole. Each luminaire contains the requisite power conversion and supply electronics and is individually oriented to direct a generally circular beam of light across the area to be illuminated, such as a sporting field or similar venue. Sports lighting systems are often subjected to harsh environments and, over time, can experience failures due to damage or simply due to wearing out of components. As the failure of a lighting system to deliver the appropriate amount of illumination can impair the use of the field being illuminated, there is a need in the art for a lighting system that can adjust for the failure of critical components and continue to deliver the desired level of illumination.

With current lighting systems, it can be difficult to evenly illuminate large sporting fields. Current solutions have problems providing enough light for athletes to play without impaired visibility while also limiting the sizes of lighting structures to avoid obstructing spectators' views. There is also a high cost associated with building and maintaining large lighting structures Accordingly, there is a need in the art for lighting system that can be more easily adjusted upon installation and during use.

### SUMMARY OF THE INVENTION

The present disclosure is directed toward systems, methods, and devices, employing laser diodes as asymmetric illumination sources.

In one aspect of the present disclosure provided herein, is an illumination system, having a luminaire having an illumination source positioned in a housing and having a plurality of columns of laser diodes, each column of laser diodes is coupled to one of a corresponding plurality of independent electrical power pathways; a power supply enclosure independent from and positioned separately from the housing of the luminaire and enclosing a plurality of laser diode drivers, each of which is interconnected via wiring harness extending between the power supply enclosure and the housing to a corresponding one of the plurality of independent electrical power pathways in the housing so that each of the plurality of laser diode drivers can output an amount of power to each of the plurality of columns of laser diodes to cause each of the plurality of columns of laser diodes to illuminate; and a microprocessor positioned in the power supply enclosure and coupled to the plurality of laser diode drivers to set an amount of power that is output from each of the plurality of laser diode drivers to the corresponding one of the plurality of columns of laser diodes, where the microprocessor is configured to increase power output from any one of the plurality of laser diode drivers if power output from any other of the plurality of laser diode drivers decreases below the amount of power set by the microprocessor.

In another aspect of the present disclosure provided herein, is an asymmetrically controllable lighting system having a housing extending along a longitudinal axis and having an elongated opening; an illumination source positioned in the elongated opening of the housing and having a plurality of columns of laser diodes, each of which is coupled to one of a corresponding plurality of independent electrical power pathways; and a coupler positioned at one end of the longitudinal axis of the housing and having a plurality of electrical contacts interconnected to plurality of columns of laser diodes via each of the independent electrical power pathways. The plurality of columns of laser diodes extends along the longitudinal axis and perpendicular to the longitudinal axis.

In another aspect of the present disclosure provided herein, is a lighting system having a luminaire having housing extending along a longitudinal axis and an illumination source positioned in an elongated opening of the housing, where the illumination source includes a plurality of columns of laser diodes, the plurality of columns extending longitudinally and perpendicular to the longitudinal axis; a core enclosure positioned remotely from the luminaire and having a plurality of laser diode drivers, each of which is interconnected to a corresponding one of the columns of laser diodes by a wiring harness extending therebetween, and a microprocessor coupled to the plurality of laser diode drivers and configured to set an amount of power output by the laser diode drivers to the columns of laser diodes, where the core enclosure is configured to convert power from an alternating current source into direct current powering the plurality of laser diode drivers; and a master enclosure having a controller in communication with the microprocessor of the core enclosure, where the controller commands the microprocessor of the core enclosure to control the amount of power output by the laser diode drivers.

These, and other objects, features and advantages of this invention will become apparent from the following detailed description of the various aspects of the invention taken in conjunction with the accompanying drawings.

### BRIEF DESCRIPTION OF THE DRAWINGS

The present invention will be more fully understood and appreciated by reading the following Detailed Description in conjunction with the accompanying drawings, in which:

FIG. 1 is a perspective view of an asymmetric source sports lighting system in accordance with an aspect of the present invention;

FIG. 2 is a perspective view of the upper portion of a support pole of an asymmetric source sports lighting system in accordance with an aspect of the present invention;

FIG. 3 is a perspective view of the asymmetric lighting source for a lighting module in accordance with an aspect of the present invention;

FIG. 4 is a mechanical view of the laser diode (LD) layout for an asymmetric lighting source in accordance with an aspect of the present invention;

FIG. 5 is schematic of the electronics for an asymmetric lighting source in accordance with an aspect of the present invention;

FIG. 6 is a perspective view of a lighting module in accordance with an aspect of the present invention having a lens array thereon;

FIG. 7 is a perspective view of the male and female couplers of a lighting module in accordance with an aspect of the present invention;

FIG. 8 is a cross-sectional view of the male and female couplers of a lighting module in accordance with an aspect of the present invention;

FIG. 9 is a perspective view of a coupler clamp for securing lighting modules to each other in accordance with an aspect of the present invention

FIG. 10 is cross-sectional view of a lighting module to lighting module connection in accordance with an aspect of the present invention;

FIG. 11 is an electrical diagram of a lighting module to lighting module connection in accordance with an aspect of the present invention;

FIG. 12 is two perspective views of a mount in accordance with an aspect of the present invention;

FIG. 13 is an electrical diagram of a lighting module to mount connection in accordance with an aspect of the present invention;

FIG. 14 is a perspective view showing axial rotation of a series of interconnected lighting modules in accordance with an aspect of the present invention;

FIG. 15 is a perspective view of a controller stack in accordance with an aspect of the present invention;

FIG. 16 is a perspective view of a core enclosure in accordance with an aspect of the present invention;

FIG. 17 is high level schematic for a lighting system in accordance with an aspect of the present invention;

FIG. 18 is a detailed schematic of a master controller in accordance with an aspect of the present invention;

FIG. 19 is a detailed schematic of a core enclosure in accordance with an aspect of the present invention

FIG. 20 is a schematic of wireless monitoring and control approach in accordance with an aspect of the present invention; and

FIG. 21 is a schematic of beam steering using a lighting system in accordance with an aspect of the present invention;

FIG. 22 is a schematic of beam angles changes using a lighting system in accordance with an aspect of the present invention;

FIG. 23 is a schematic of tunable cut-off in a lighting system in accordance with an aspect of the present invention;

FIG. 24 is a perspective view of an environmental sealing system for a lighting module in accordance with an aspect of the present invention;

FIG. 25 is a front view of an environmental sealing system for a lighting module in accordance with an aspect of the present invention;

FIG. 26 is a side view of a micro-lens for a lighting module in accordance with an aspect of the present invention;

FIG. 27 is a first view of illumination steering using a lens array in accordance with an aspect of the present invention;

FIG. 28 is a second view of illumination steering using a lens array in accordance with an aspect of the present invention;

FIG. 29 is a third view of illumination steering using a lens array in accordance with an aspect of the present invention; and

FIG. 30 is a fourth view of illumination steering using a lens array in accordance with an aspect of the present invention.

### DETAILED DESCRIPTION OF THE INVENTION

The present invention will be discussed in detail in terms of various exemplary embodiments according to the present invention with reference to the accompanying drawings. In the following detailed description, numerous specific details are set forth to provide a thorough understanding of the present invention. To those skilled in the art, it will be obvious that the present invention may be practiced without these specific details. Similarly, well-known structures are not described to avoid obscuring the present invention.

Thus, the implementations described below are exemplary implementations provided to enable persons skilled in the art to make or use the embodiments of the disclosure and are not intended to limit the scope of the disclosure, which is defined by the claims.

Furthermore, there is no intention to be bound by any expressed or implied theory presented in the preceding technical field, background, summary, or the following detailed description. It is also to be understood that the specific devices and processes illustrated in the attached drawings, and described in the following specification, are simply exemplary embodiments of the inventive concepts defined in the claims. Specific dimensions and other physical characteristics relating to the embodiments disclosed are not to be considered as limiting, unless the claims expressly state so.

Likewise, the various figures, steps, procedures, and workflows are presented only as an example and in no way limit the systems, methods, or apparatuses described to performing their respective tasks or outcomes in different timeframes or orders. Unless expressly stated, any method set forth herein shall not be construed as requiring that its steps be performed in a specific order. The teachings of the present invention may be applied to any asymmetric lighting system.

The various embodiments described herein provide for systems, devices, and methods for asymmetric lighting systems: particularly, for asymmetric source lighting systems for sports and including asymmetric source sports lighting systems with auxiliary lighting systems.

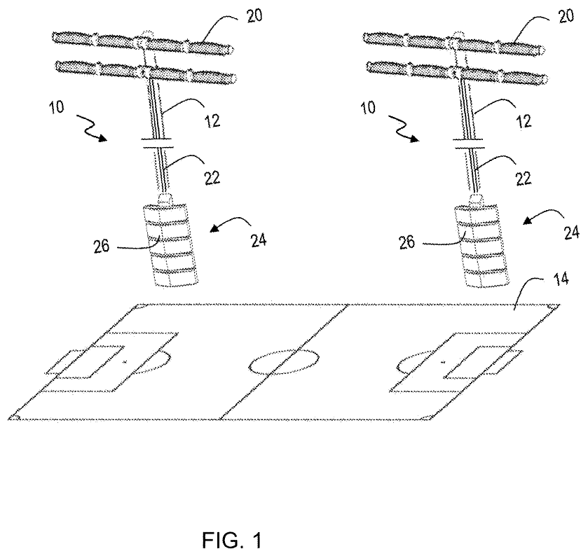

Referring to the figures, wherein like numeral refer to like parts throughout, there is seen in FIG. 1 an asymmetric source sports lighting system 10 according to the present invention. System 10 is designed for installation on a support pole 12 to provide illumination over a target area 14, such as a sporting field or pitch. System includes one or more columns of laser diode (LD) lighting modules 20 that extend laterally from support pole 12. Lighting modules 20, may also be referred to luminaires. Lighting modules 20 are powered via a wiring harness 22 that extends along the interior of support pole 12 and is coupled to a controller stack 24. Controller stack 24 transforms local building power from AC to DC and includes LD drivers 26 for lighting modules 20. In certain embodiments, a battery may be connected to support pole 12, by internal wiring to the controller stack 24. The controller stack 24 may charge the battery from transformed local building power while AC power is received by a power supply. In the event of black-out or brown-out conditions or a drop below a threshold voltage, the power supply may be switched to battery power the lighting modules 20 or a subset of lighting modules.

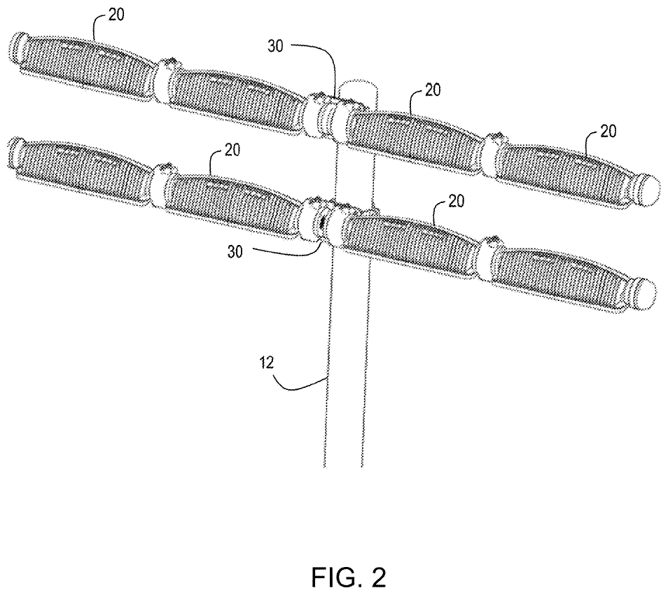

Referring to FIG. 2, a central mount 30 is coupled to pole 12 and used to support first and second lighting modules 20. Lighting modules 20 are coupled to either side of mount 30 using a modular coupling system described herein that physically supports modules 20 and electronically interconnects modules 20 to wiring harness 22 and thus controller stack 24.

The opposing end of each lighting module 20 coupled to mount 30 may be used to physically support and electronically interconnect to additional lighting modules 20 extending further outwardly from support pole 12. The combination of lighting modules 20 connected to mount 30 and the additional lighting modules 20 extending to either side of pole 12 are self-supporting so that support pole 12 does not need to include physical cross-arms or lateral supports to mount additional lighting modules 20. The particular dimensions of lighting module 20 may be varied as desired. For example, lighting module 20 could be provided in two lengths, X and 2X, that may be mixed and matches as needed for a particular installation.

Continuing with reference to FIG. 2, two sets of lighting modules are depicted. In certain embodiments, one of the two sets of lighting modules may be, for example, auxiliary emergency lighting. Auxiliary emergency lighting may be turned off during normal lighting conditions and activated when emergency conditions arise. In certain other embodiments, auxiliary emergency lighting 200 may operate during normal lighting conditions but remain activated during emergency conditions.

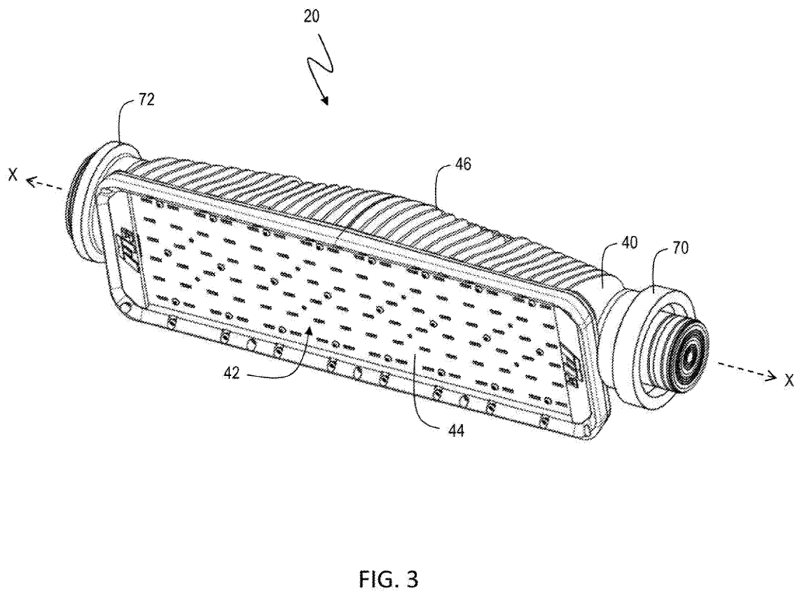

Referring to FIG. 3, each lighting module 20 includes a housing 40 extending along a longitudinal axis X-X. Housing 40 defines a rectangular opening 42 in a central portion thereof that permits access to an asymmetric illumination source 44. Asymmetric illumination source 44 is dimensioned to produce a rectangular beam of illumination from rectangular opening 42 of module 20. Housing 40 may further include fins 46 or other external structures for dispersing heat generated by the use of asymmetric illumination source 44.

In other embodiments, a closed cooling system may be connected to the lighting module 20. Lighting module 20 may have openings within housing 40 into which cooling tubes or cooling pipes are inserted through the lighting module 20. The cooling tubes or pipes may be part of a closed cooling system including a pump and/or compressor connected to the cooling tubes. The cooling tubes of the closed cooling system may have cooling fluid circulating within the pipes and providing cooling for the lighting module 20. In certain embodiments, the closed cooling system may pass through a plurality of lighting modules (e.g., lighting module 20), while in other embodiments, each lighting module may have its own closed cooling system.

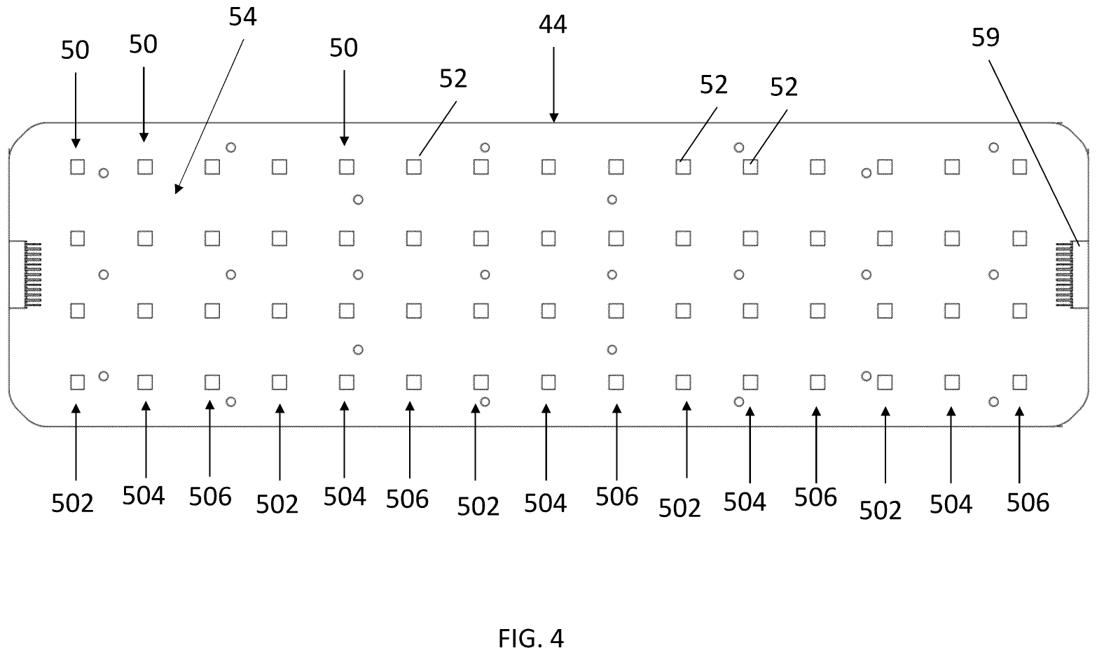

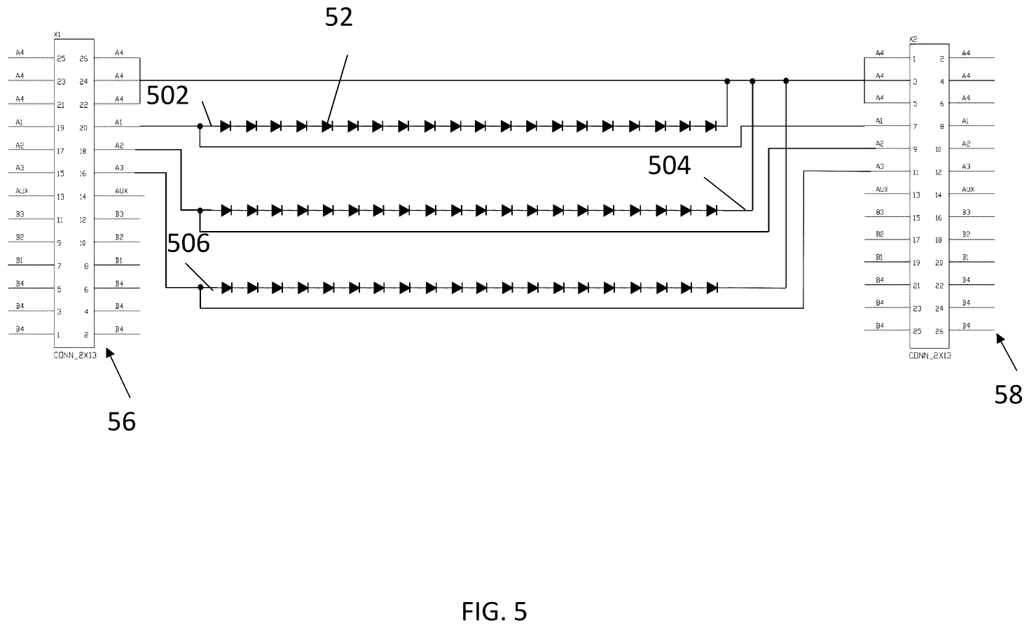

Referring to FIGS. 4 and 5, asymmetric illumination source 44 has multiple column sets 50 of laser diodes (LDs) 52 spaced along a substrate 54 and coupled to a connector 59 coupled to electronic circuitry 56 for asymmetrically driving illumination source 44. The illumination source 44 may also be referred to as a laser diode array. In FIG. 4, three column sets 50 of LDs 52 are shown, a first column set 502, a second column set 504, and a third column set 506. Each column set 50 is independently controllable by adjusting the amount of power delivered to that column set using electronic circuitry 56 and controller stack 24 to provide asymmetric illumination from module 20. Optionally, a local microcontroller in each module 20 can be for further adjustment of the amount of power provided to each column of LD sets 50.

In certain embodiments, super luminescent diodes may be used in place of or in addition to laser diodes.

As seen in FIG. 5, asymmetric illumination source 44 having three independently controllable column sets 50 of LDs 52. Each column of column set 50 has a plurality of LDs (e.g., LDs 52). Electronic circuitry 56 further includes pass-through circuity 58 for providing power to adjacently connected lighting modules 20 that also include independently controlled column sets 50 of LDs 52. For example, Aux, B1, B2, B3, and B4 are all straight pass thru. In the example of FIG. 5, a total of two additional lighting modules 20 may be interconnected and supported by circuitry 58.

Each of LDs 52 may be a small volume optic and point source with a high peak candela. By using laser diodes as opposed to LEDs or other light sources, the number of individual lighting sources would be reduced. LDs also have a higher intensity, speed, and consistency than LEDs or other light sources. The light source produced by the laser diodes originates out of a single source and may illuminate brighter and reach farther than LEDs. For current stadium lighting, especially large fields, the fixtures are located on top of high structures or positioned sufficiently far from the field, that shadows and dark spots may exist on the field. Since LDs 52 are a coherent light source, by manipulating the light's diffraction, the light may be focused where needed and provides for coverage for large fields. Light diffraction may be manipulated through the use of one or more silicone elements positioned to diffract light emitted by each of LDs 52.

The laser diodes may be emitted at a phosphor plate to create white lighting. In other embodiments, the LD may be emitted as red, green, and blue light, which may be manipulated to provides for emission of white light without the use of phosphor.

With reference to the longitudinal axis X-X of FIG. 3, each column of column sets 50 of FIG. 4, may be perpendicular to longitudinal axis X-X, with column sets 50 extending along longitudinal axis X-X.

Columns of LDs 52 are depicted in FIG. 4, with the columns grouped into column sets 50, with the column sets 50 as in FIG. 5, controlled by drivers. In other embodiments, individual columns of LDs may each correspond and be controlled by a corresponding driver, with corresponding circuitry and connectors configured to accommodate control of each individual column of laser diodes.

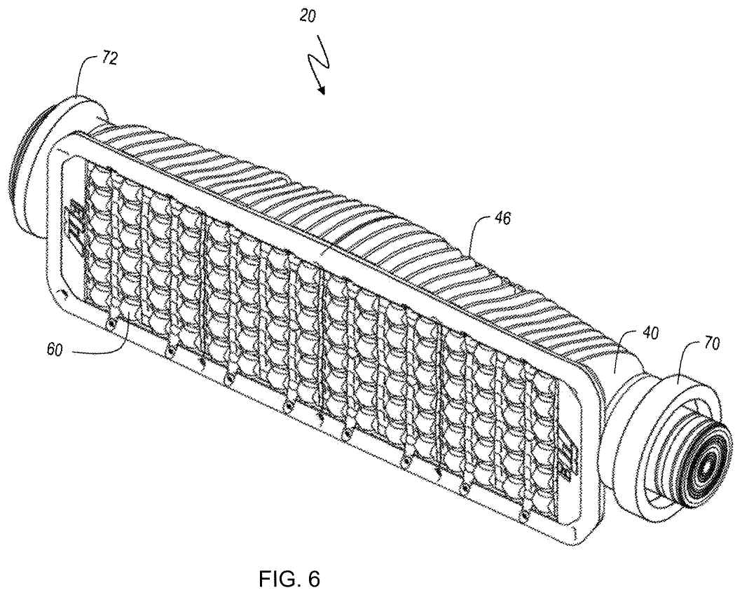

Referring to FIG. 6, a molded lens array 60 is positioned over an asymmetric illumination source 44 to reduce harshness and provide sealing of asymmetric illumination source 44 within housing 40. Housing 40 of module 20 is further configured to allow for easy coupling to the support pole and to other housings 40, forming both structural and electrical connection. Housing 40 includes a male coupler 70 positioned at one end of housing 40 and a female coupler 72 positioned at an opposing end of housing 40. Male coupler 70 is defined by a radially extending flange 74 and a circumferentially extending, outwardly facing bearing surface 76. Female coupler 72 includes a correspondingly dimensioned flange 78 and a receptacle 82 defining a circumferentially extending, inwardly facing bearing surface 77.

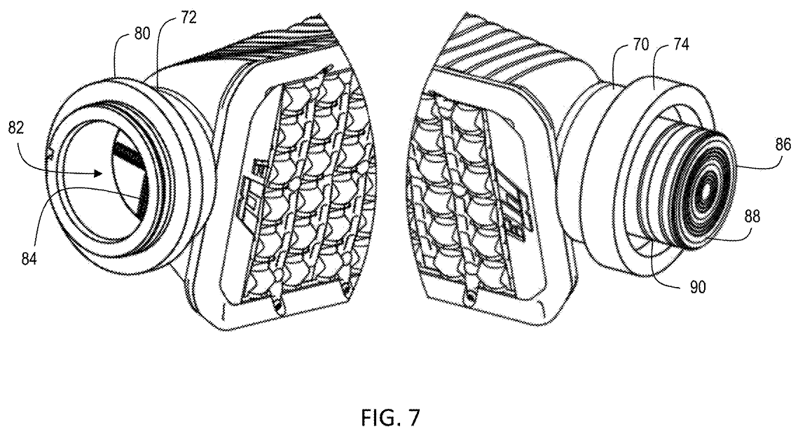

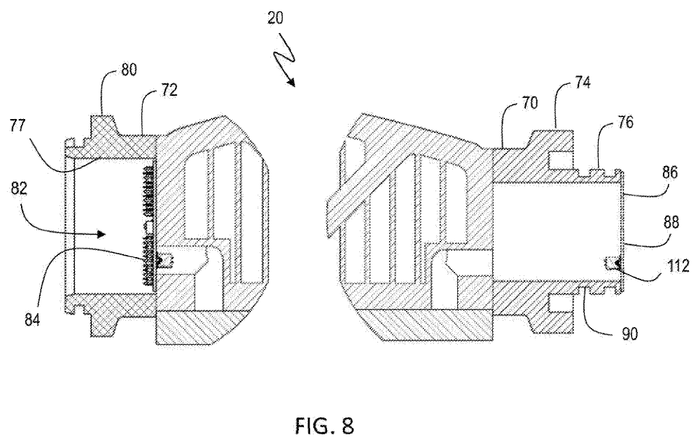

Referring to FIGS. 7 and 8, female coupler 72 further includes a set of brush contacts 84 positioned in receptacle 82 that face outwardly along axis X-X and male coupler 70 includes an end face 86 supporting set of ring contacts 88 that face outwardly in the opposite direction along axis X-X from brush contacts 84. Male coupler 70 may additionally include grooves 90 formed therein to house an O-ring for sealing purposes. It should be recognized that other contacts may be used, such as pogo pins and the like. As detailed below, brush contacts 84 and ring contacts 88 define a plurality of independent pathways for powering the independently controlled column sets 50 of LDs 52.

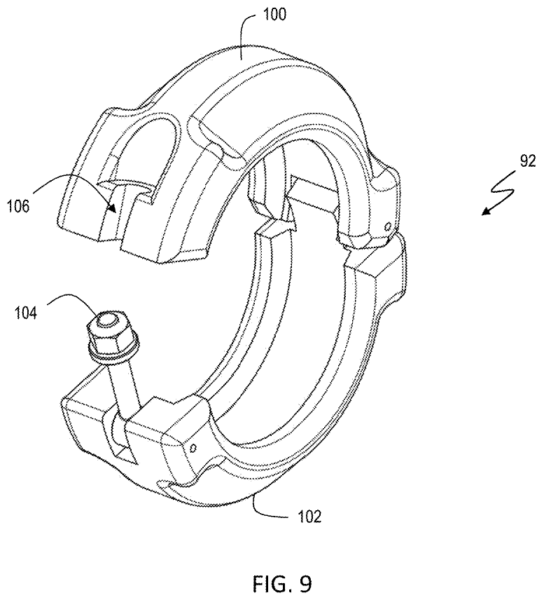

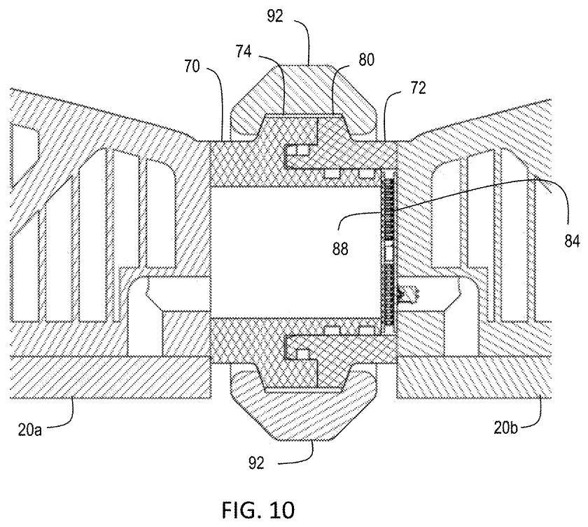

Referring to FIGS. 9 and 10, a clamp 92 may be positioned and secured in covering relation to flanges 74 and 80 to secure a first module 20a to a second module 20 b when male coupler 70 and female coupler 72 are full joined so that bearing surfaces 76 and 77 are in seated together and brush contacts 84 and ring contacts 88 are in contact and electrically engaged. Clamp 92 comprises a pair of jaws 100 and 102 that can be opened and then closed in covering relation to flanges 74 and 80, as seen in FIG. 10, when male coupler 70 of one module 20a is jointed with and seated inside female coupler 72 of an adjacent module 20b. When male coupler 70 is fully inserted into female coupler 72, flanges 74 and 80 will abut and brush contacts 84 will physically and electrically engage ring contacts 88. Clamp 92 may then be closed over flanges 74 and 80 to secure first module 20a to second module 20b using a latch 104 on one jaw 102 that cooperates with a slot 106 in the other jaw 100, with electrical continuity between first module 20a to second module 20b provided via the engagement of ring contacts 88 with brush contacts 84. Adjacent modules 20 may thus be electrically interconnected when coupled together so that each module 20 has multiple independent electrical power pathways for driving the independently controllable LD columns of asymmetric illumination source 44.

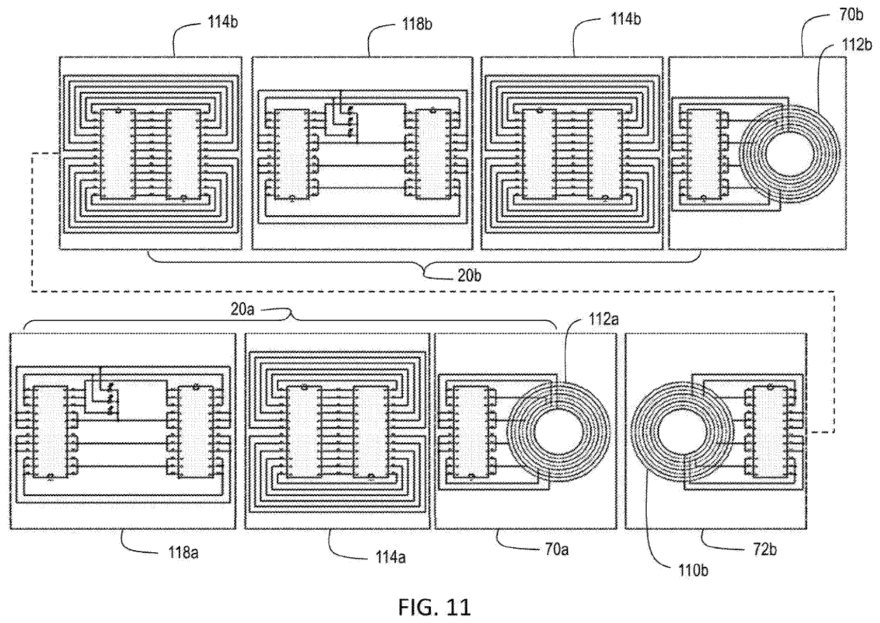

Referring to FIG. 11, module 20b is electrically interconnected to module 20a so that LD circuitry 118b of module 20b and LD circuitry 118a of module 20 are coupled together and under common power control. For example, coupler 70b of module 20b includes coupler circuitry 112b that can receive power from ring contacts 88. Coupler circuitry 112b is coupled to LD circuitry 118b via cabling 114b. LD circuitry 118b is also coupled to coupler circuitry 110b associated with female coupler 72b via cabling 114b. As a result, independent power pathways for LD circuitry 118b extend through module 20b and are available at coupler 70b and coupler 72b such as that a power supply connected to coupler 70 will also provide power to coupler 72, and vice versa. As further seen in FIG. 11, module 20a can be electrically coupled to module 20b via a coupler 70a that is secured to coupler 72b. Coupler circuitry 112a of module 20a is coupled to LD circuitry 114a via cabling 114a. Although not illustrated for simplicity, it should be evident that module 20a also include a coupler 72a that can be, in turn, coupled to another module 20, and so on, with the power supply for all housings 20 connected to an available coupler 70 or 72 at either end. Thus, module 20 is bi-directional and can be placed in series with additional housings 20 for common power control.

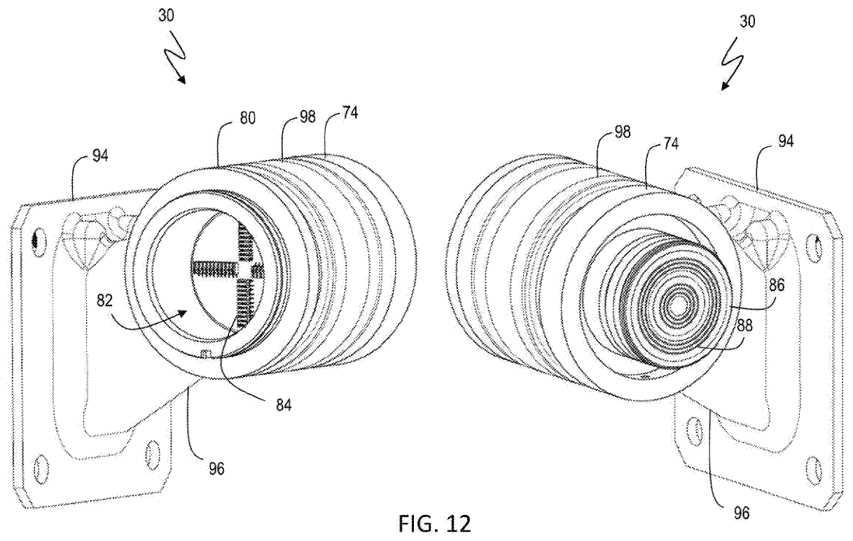

Referring to FIG. 12, mount 30 for attaching one or more housings 20 to a support pole 12 comprises a mounting plate 94 having a shaft 96 extending therefrom to support a main body 98 having male coupler 70 on one side and a female coupler 72 on the opposing side. Mount 30 suspends module 20 in spaced relation to support pole 12 to which mount 30 is attached. Male coupler 70 and female coupler 72 are configured in same manner as described above with respect to module 20, i.e., male coupler 70 includes an end face 86 having concentric ring contacts 88 and female coupler 72 has brush contacts 84 positioned within receptacle 82. Male coupler further includes flange 74 and female coupler 72 includes flange 80. As a result, module 20 may be coupled to mount 30 in the same manner as described above with respect to the connection of module 20a to module 20b.

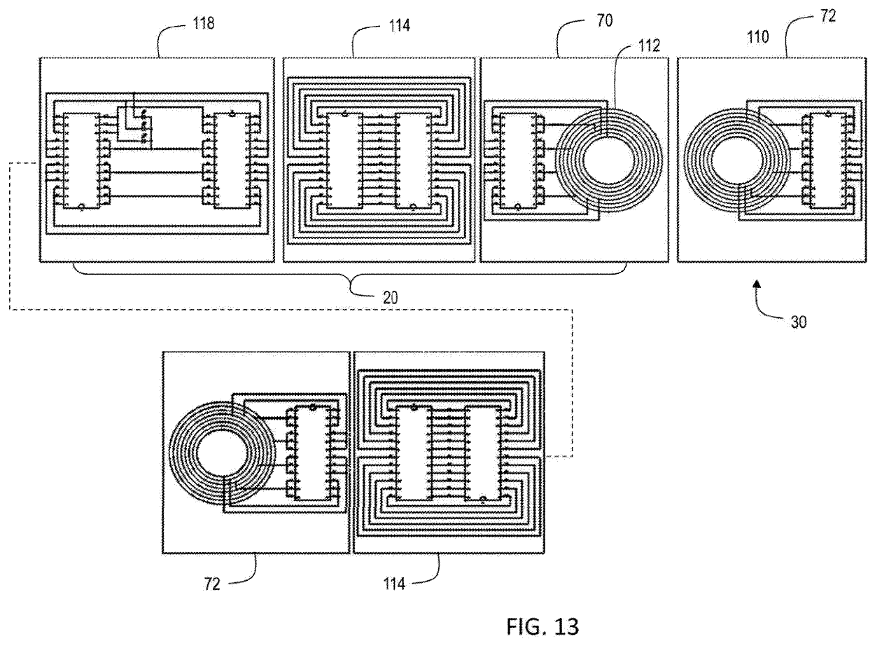

Referring to FIG. 13, joining of mount 30 to module 20 allows coupler circuitry 110 of female coupler 72 of mount 30 to connect with coupler circuitry 112 of male coupler 70 of module 20 via brush contacts 84 and ring contacts 88. Coupler circuitry 112 is coupled to LD circuitry 118 via cabling 114. LD circuitry 118 is also coupled to coupler circuitry 110 associated with female coupler 72 via cabling 114. As a result, independent power pathways for LD circuitry 118b extend through module 20 from mount 30 and are available at coupler 70 such that a power supply connected to coupler 72 will also provide power to coupler 70. Similarly, module 20 may also be connected to the male coupler 70 of mount 30 using female coupler 72 of module 20, thus simply reversing the connections of FIG. 13 such that power is provided by mount 30 to coupler 72 with the power also made available at coupler 70 for attachment of another module 20.

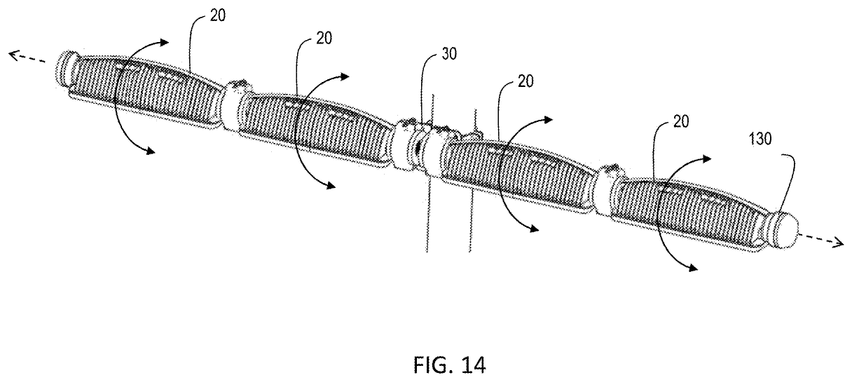

Referring to FIG. 14, cylindrical bearing surfaces of male coupler 70 and female coupler 72 allows adjacent lighting modules 20, as well as lighting modules 20 coupled to mount 30, to be rotated about longitudinal axis X-X. The orientation of the rectangular illumination provided by module 20 may thus be adjusted in a single direction, i.e., about a single axis, via rotation of lighting module 20 about axis X-X. As explained above, bearing surfaces 76 and 77 allow for physical rotation of housings 20, with brush contacts 84 and ring contacts 88 maintaining electrical continuity regardless of the rotation of housing about longitudinal axis X-X. Housings 20 may thus be easily oriented, or reoriented, as desired. While housings 20 may be manually adjusted at any time, servo motors could be incorporated into couplers 70 and 72 to allow for remote rotation of lighting modules 20 about axis X-X.

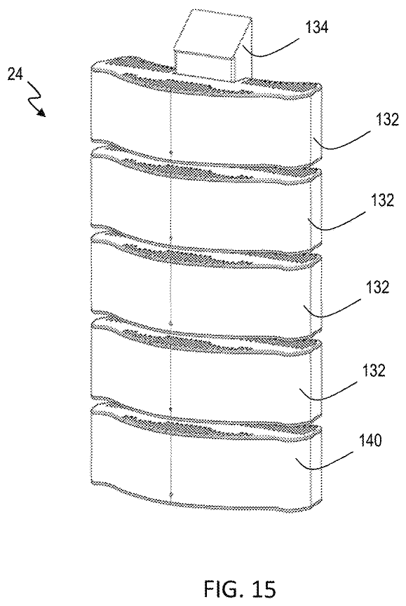

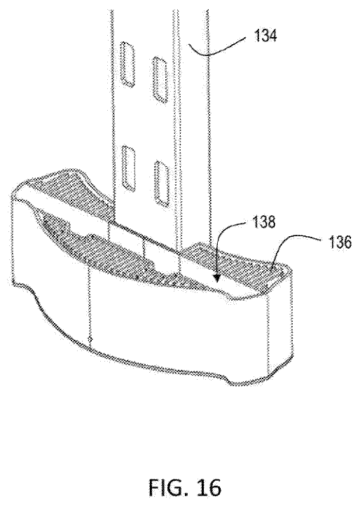

Referring to FIGS. 15 and 16, controller stack 24 comprises a series of core enclosures 132, each of which houses the power conversion and laser diode electronics, typically referred to as LD drivers, for an associated lighting module 20, as well as a master enclosure 140 that provides housekeeping functions. Controller stack 24 includes a back plane 134 that provides the electrical interconnections between each core enclosure 132 and master enclosure 140 as well as the requisite interconnections to wiring harness 22 to interconnect controller stack 24 to lighting modules 20. Back plane 134 is preferably adapted to act as a heat sink and transfer excess heat to support pole 12 for additional dispersion of heat generated by controller stack 24. As seen in FIG. 16, core enclosure 132 and/or master enclosure 140 include ribs 136 for dissipation of heat generated by internal electrical components positioned in a central cavity 138.

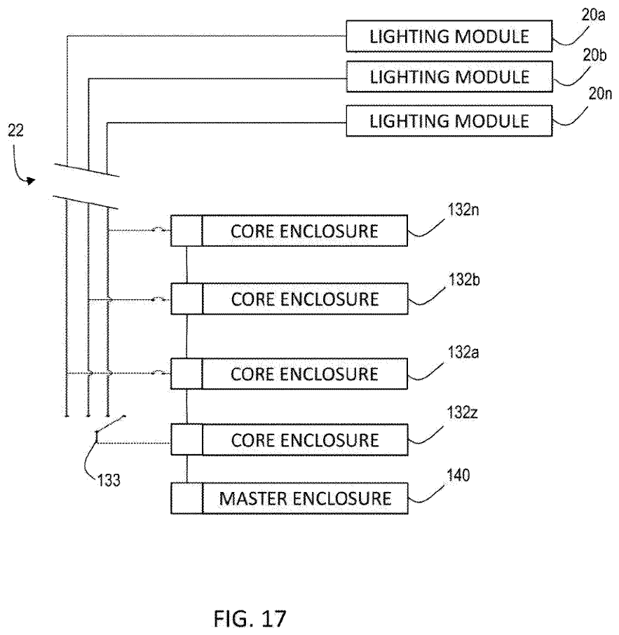

Referring to FIG. 17, each core enclosure 132a, 132b . . . 132n is associated with and coupled via wiring harness 22 to a corresponding lighting module 20a, 20b . . . 20n. Preferable, a backup core enclosure 132z is selectively coupled to each lighting module 20a, 20b . . . 20n via a switching circuit 133 to provide a backup power supply in the event of a fault in any of core enclosure 132a, 132b . . . 132n. For example, if a fault in any core enclosure 132 results in the loss of illumination from any or all of the independently controlled column sets 50 of LD 52 in the corresponding lighting module 20, power to that lighting module 20 can be switched to the backup core enclosure 132z to maintain the desired amount of illumination until such time as the faulty core enclosure 132 can be repaired or replaced. Each core enclosure 132a, 132b . . . 132n is also interconnected to master enclosure 140, which supervises and controls via digital commands the local operation of each core enclosure 132a, 132b . . . 132n.

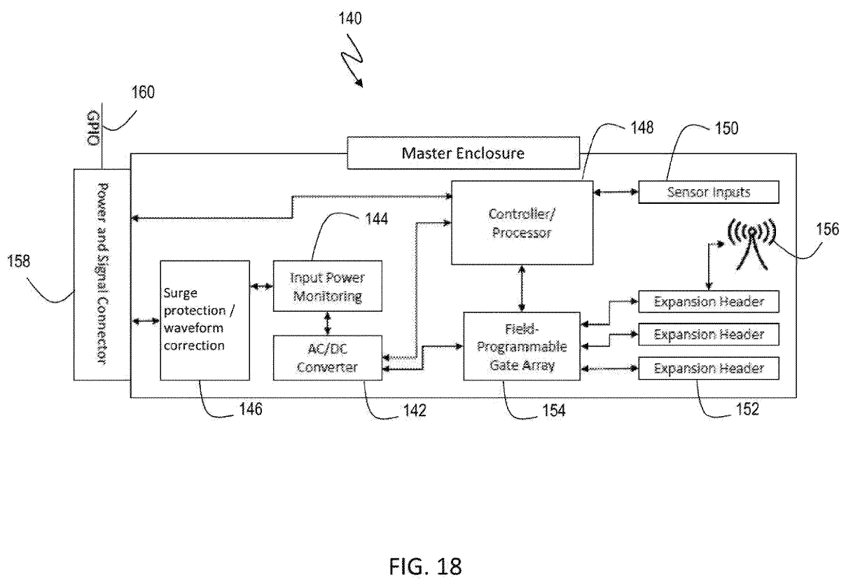

Referring to FIG. 18, master enclosure 140 is coupled to AC power via a power and signal connector 158 and includes local AC/DC conversion 142 with input power monitoring 144 as well as surge protection and waveform correction 146. Master enclosure 140 also includes a controller/processor 148 that has sensor inputs 150 for monitoring of system 10. Controller/processor 148 is also interconnected to a series of expansion headers 152 and wireless communication interface 156 via a field programmable gate array (FPGA) 154. Controller/processor 148 may thus be programmed to establish connection with a remotely positioned host system or remote device (such as a tablet or smartphone) that can provide commands controlling operation of lighting modules 20 using expansion headers 152 to provide the desired wireless connectivity. Communication could comprise any conventional wireless communication technology or protocol, such as WiFi, Blutetooth®, BLE, ZigBee, Z-Wave, 6loWPAN, NFC, cellular such as 4G, 5G or LTE, RFID, LORA, LoRaWAN, Sigfox, NB-IoT, or LIDAR. Controller/processor 148 is also coupled via power and signal connector 158 for communication with core enclosures 132, such as via a general-purpose input/output (GPIO) line 160, extending in back plane 134.

Referring to FIGS. 17 and 18, each core enclosure 132 is associated with and coupled via wiring harness 22 to a corresponding lighting module 20. In certain embodiments, the master controller 140 has a circuit 133 in connected to the power supply a configured to switch to power from battery. Master enclosure 140 includes electronics for supervision and control of each core enclosure 132. For example, in certain embodiments master enclosure 140 may include a switching module which may a include circuit configured to detect a drop in voltage to the main lights and provide instructions to each core enclosure 132 to switch from the AC power supply to battery when the voltage drop is at or below a threshold value. In this embodiment, once a voltage drop occurs, a black out or brown-out situation may occur and other equipment may cease operating. The master controller 140 may be connected to cameras or emergency communication systems and may activate such systems. The master controller may also, for example, signal officials or other auxiliary power systems.

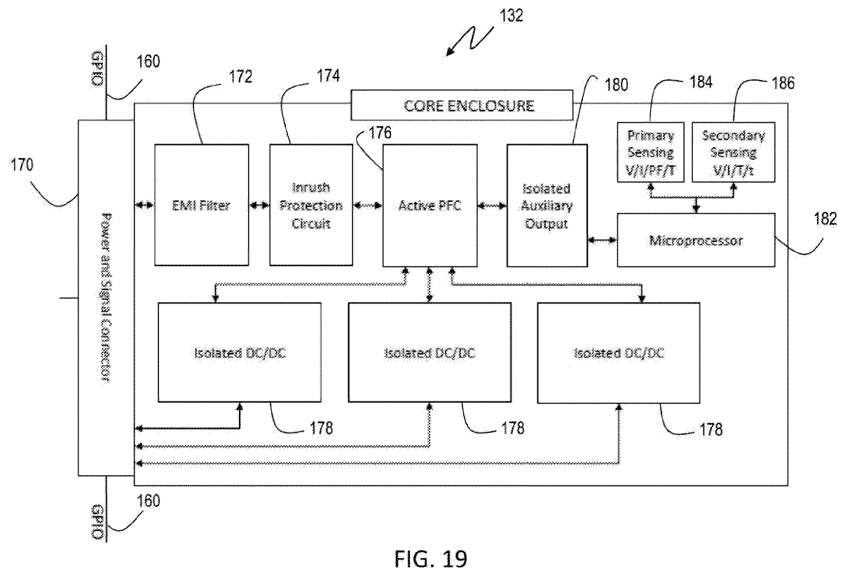

Referring to FIG. 19, each core enclosure 132 includes a power and signal connector 170, which provides connectivity to master enclosure 140 via GPIO line 160 as well as to a connection to AC power. Core enclosure 132 provides power conversion to DC and power conditioning via an EMI filter 172, an inrush protection circuit 174 and an active power factor corrector (PFC) 176. A plurality of isolated DC/DC circuits 178, each of which supports a corresponding one of independently controllable LD columns of asymmetric illumination source 44, are coupled to active PFC 176. The present invention is illustrated with three isolated DC/DC circuits because the exemplary illumination source 44 has three independently powered columns of LDs, but if asymmetric illumination source 44 included four independently controlled column sets 50 of LDs 52, four isolated DC/DC circuits 178 would be included. Core enclosure 132 further comprises an isolated auxiliary output 180 coupled to a microprocessor 182. Microprocessor 182 is further coupled to primary sensing circuits 184 and secondary sensing circuits 186 for monitoring voltage, current, power factor, and temperature across system 10. Microprocessor 182 is further configured to adjust the power output from each of the plurality of isolated DC/DC circuits 178 based on monitoring of primary sensing circuits 184 and secondary sensing circuits 186. For example, if one of independently controlled column sets 50 of LDs 52 is not operational, microprocessor 182 can adjust the power output from the isolated DC/DC circuits 178 for the other of the independently controlled column sets 50 of LDs 52 to compensate for the loss and ensure that asymmetric illumination source 44 is providing the desired amount of illumination. For example, the microprocessor 182 is configured to increase power output from any one of the plurality of LD drivers if power output from any other of the plurality of LD drivers decreases below an amount of power set by the microprocessor 182. The microprocessor 182 may also compensate for any of the plurality of column sets 50 of LDs 52 that are not operating properly.

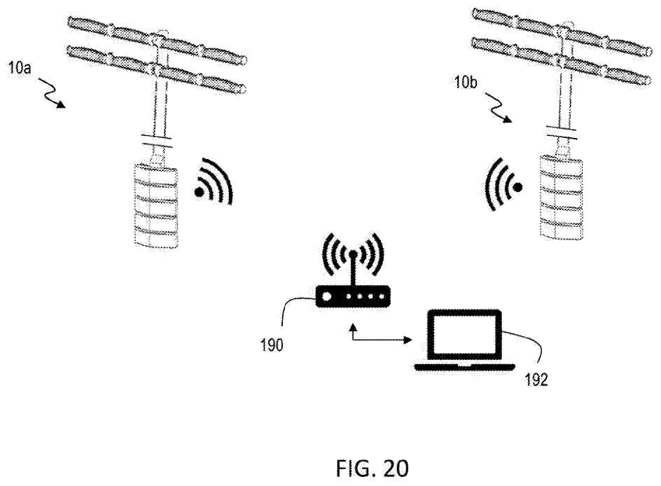

Referring to FIG. 20, the wireless communication capability of master enclosure 140 provides a third layer of redundancy in the event of a partial or total loss of illumination from lighting module 20. For example, a detected loss at one location of system 10a may be communicated to wireless gateway 190 and remote host 192. The illumination output of another system 10b may then be adjusted accordingly, either by allowing a user to send a command to system 10b to adjust power to lighting modules 20 to compensate for the detected loss or by supervisory software residing on host 192 that automatically sends the appropriate commands.

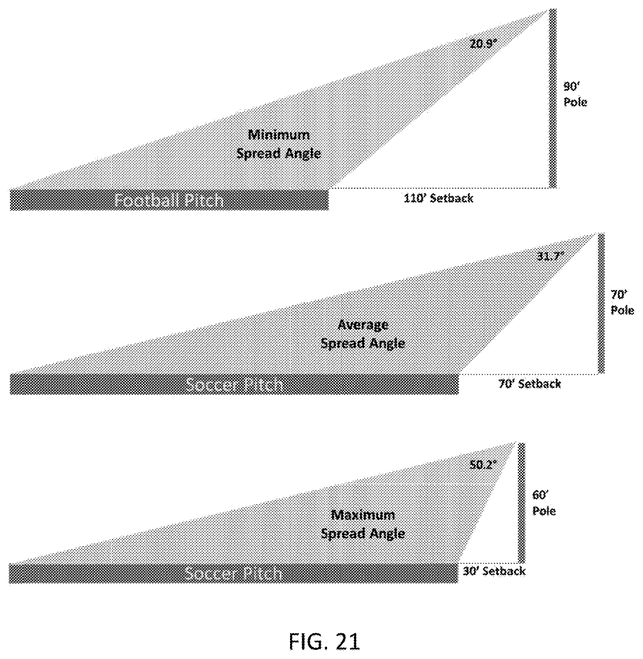

Referring to FIG. 21, asymmetric illumination source 44 of each module 20 allows for remote beam steering of lighting system 10. Lighting system 10 may be adapted to a particular installation regarding of the width of the pitch to be illuminated, the height of support pole 12, and the distance between support pole 12 and the targeted pitch. For example, asymmetric illumination source 44 may be driven to change the beam angle (generally recognized as the region of illumination with at least fifty percent of the maximum beam strength) to provide the appropriate amount of illumination between a minimum and maximum spread angle encountered in an installation. In the first scenario of FIG. 19, where the height of support pole 12 and setback distance require a minimum spread angle, asymmetric illumination source 44 can be driven asymmetrically in a first configuration to provide a narrow beam angle without having to physically reorient modules 20. In the last scenario, where the height of pole 12 and setback distance require a minimum spread angle, asymmetric illumination source 44 can be driven asymmetrically in a different configuration to provide a broader spread angle without having to physically reorient modules 20. Thus, the effective positioning of modules 20 can be adjusted without actually having to physically reorient modules 20. Thus, modules 20 may be asymmetrically driven to change the illumination scenario for different events or conditions, or to simply adjust the illumination in a given location without having to physically move lighting modules 20.

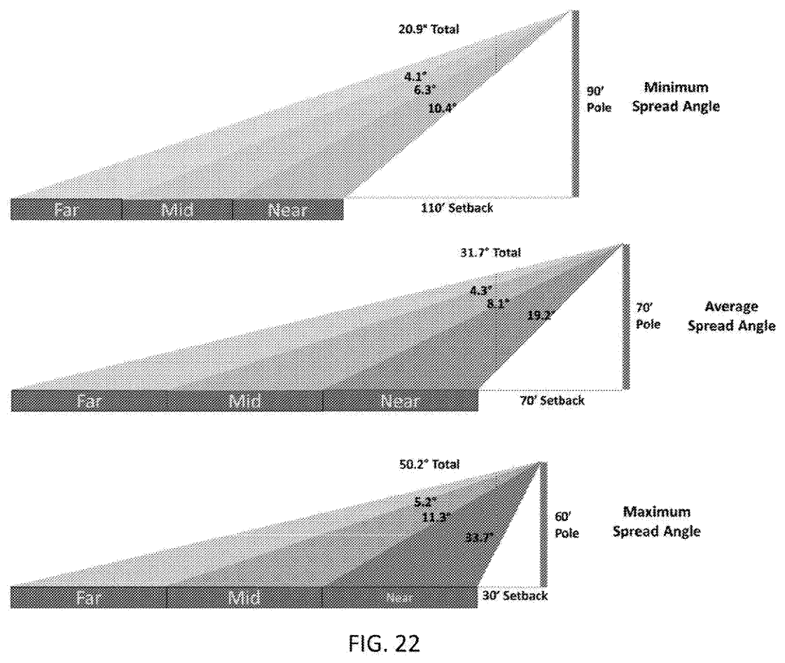

FIG. 22 illustrates how the power control over each set of columns 50 of asymmetric illumination source 44 can be adjusted to impact the beam angle emitted from lighting module 20 without having to rotate lighting module 20.

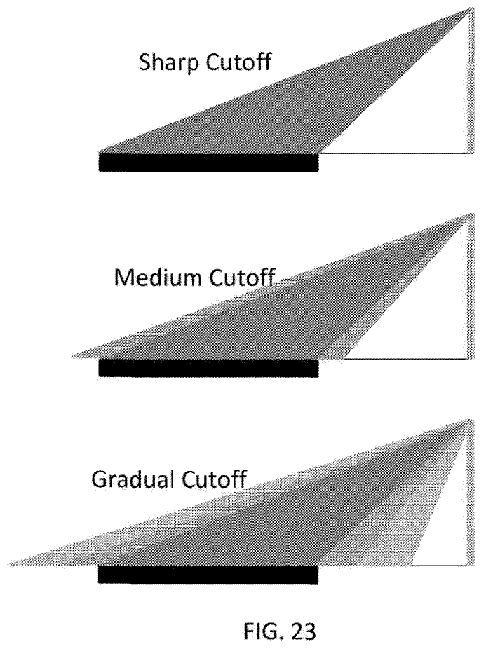

Referring to FIG. 23, asymmetric illumination source 44 of each lighting module 20 provides for a tunable cut-off for the illumination generated from lighting module 20. Illumination cut-off generally refers to the amount of illumination in the beam field that extends beyond the desired beam angle (any area of illumination with less than fifty percent but more than ten percent of the maximum beam strength). For example, in the first scenario of FIG. 23, the cut-off is very sharp, i.e., there is very little spillage beyond the main beam angle. In the second and third scenarios, the spillage increases such that more illumination is provided ancillary to the primary beam angle. Asymmetric illumination source 44 may be driven to change the cut-off at any time, whether finally upon installation, or dynamically over time to change the lighting scheme as desired by a user for different applications. For example, a gradual cut-off may be selected when more light is desired in the areas surrounding a pitch for a particular event, such as a pre-game show, and then adjusted to provide a sharp cut-off during a game. Thus, asymmetric illumination source 44 allows for control over both the beam angle and the beam field relative to each other and relative to the illumination target.

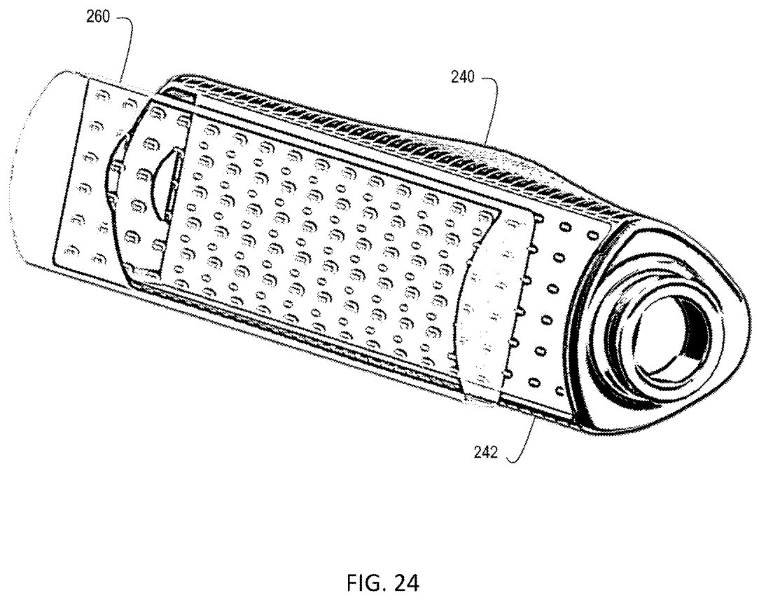

Referring to FIG. 24, lighting module 20 may be constructed using a housing 240 that encloses an asymmetric illumination source 244 and is environmentally sealed prior to attachment of lens array 260.

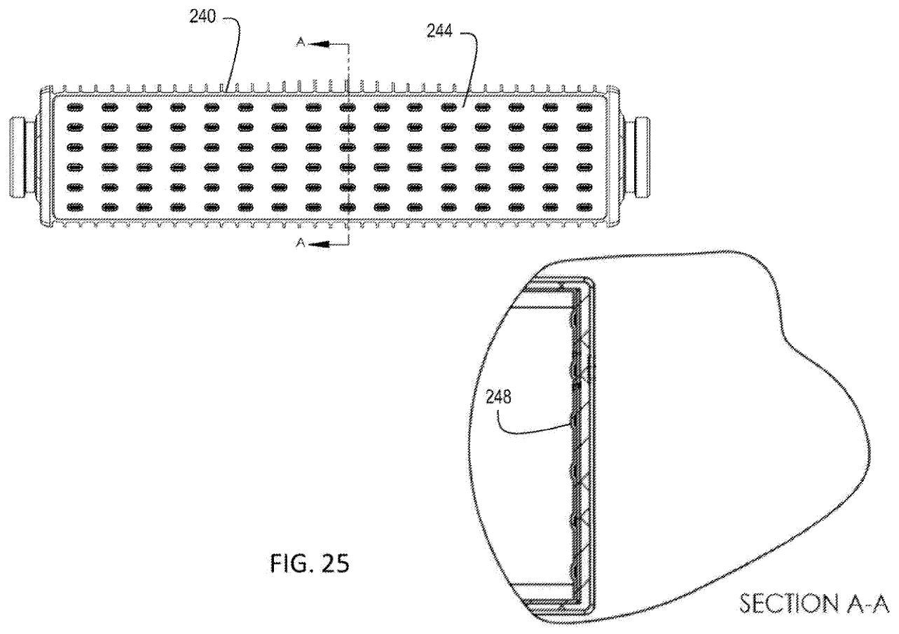

As seen in FIG. 25, housing 240 includes a resilient optical layer 248 positioned over asymmetric illumination source 244 and captured within rectangular opening 242 to seal housing 240 from environmental infiltration. As a result, lens array 260 may be attached or removed from housing 240 in the field, such as to adjust the optical conditioning being provided, without compromising the environmental integrity of housing 240. Optical layer 248 is preferably formed from a moldable optical silicone, such as SILASTIC® MS-1002 moldable silicone and related moldable silicone compounds.

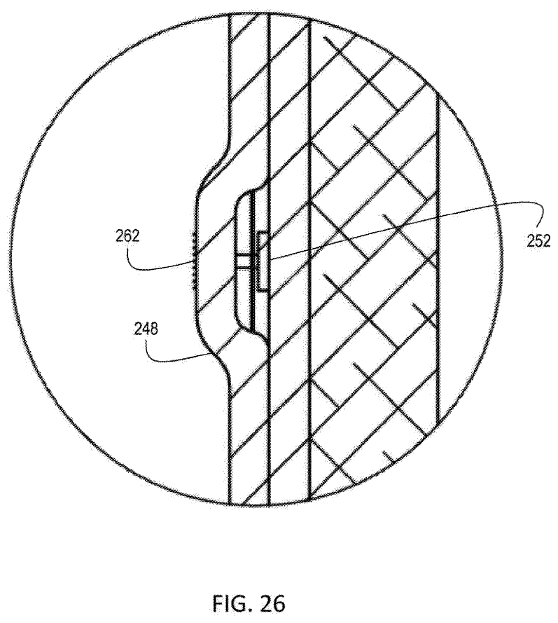

As seen in FIG. 26, optical layer 248 may include micro-lenses 262 molded therein and in alignment with each LD 252 of asymmetric illumination source 244. Optical layer 248 thus performs pre-modulation of the illumination from lighting module 20. Micro-lenses 262 allow for finer optical texturing than with lens array 260 alone. In addition, as lens array 260 does not need to perform as much optical conditioning, lens array 260 can be smaller and thus lighter than otherwise possible.

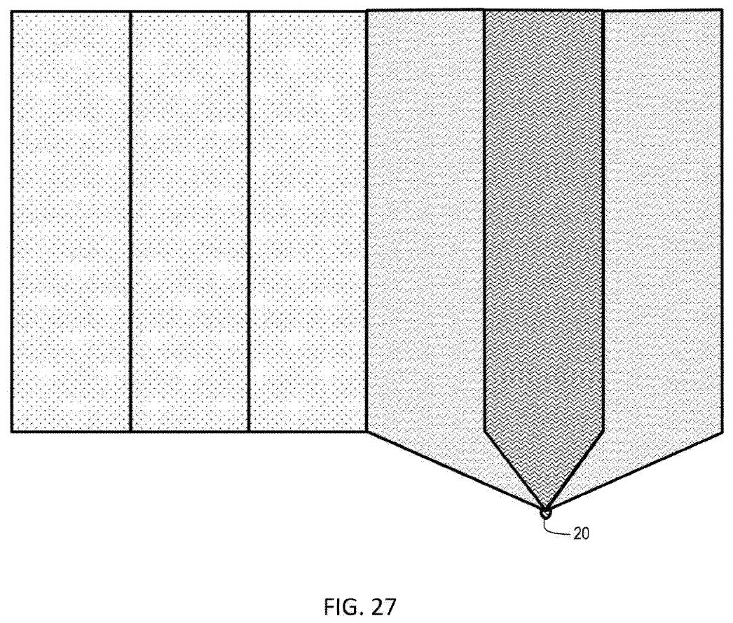

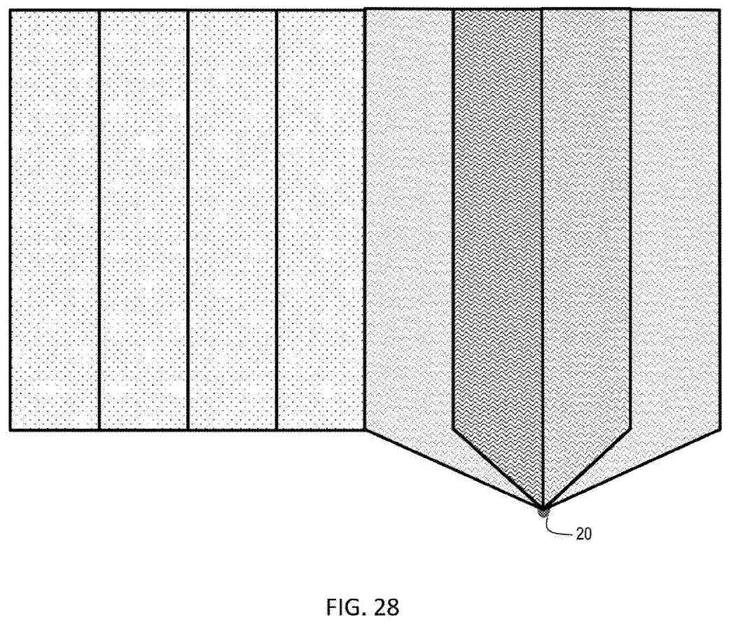

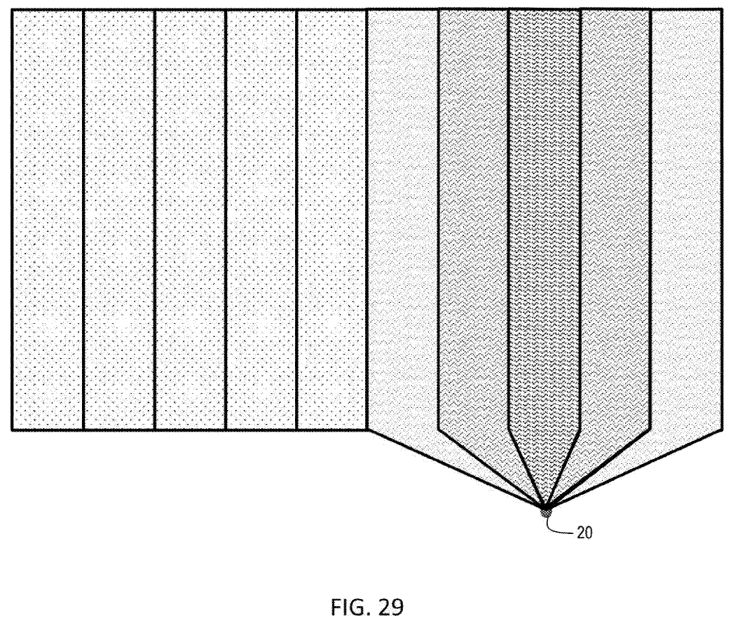

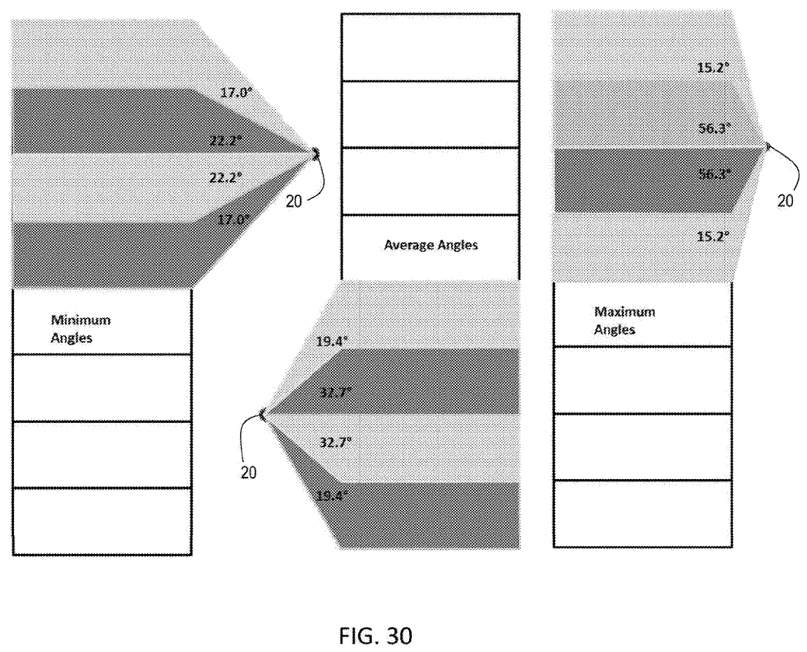

Referring to FIGS. 27 through 30, lighting module 20 may be outfitted with lens array 60 configured that steers illumination into three, four, or five different regions. For example, each particular installation may include a different number of support poles 12, so an appropriate lens array 60 distributing illumination into three, four, or five different regions may be used. As is known in the field, illumination from each support pole 12 may need to overlap with illumination for other support poles 12 to provide the desired illumination, reduce or control shadowing, etc. As seen in FIG. 30, lighting module 20 can provide a wide or narrow area of illumination using variously designed lens arrays 60 to steer illumination between a minimum and maximum distribution angle.

Referring to FIGS. 3-5, 7, 8, and 16, asymmetric illumination source 44 or laser diode array may include heat tubes to transfer or conduct heat away from the laser diodes to promote optimal performance and LD longevity. The heat tubes may be in direct contact with the laser diode array 44, transferring heat to a heat sink. The heat sink may be integrated into the diode array 44. In another embodiment, the heat sink may be integrated with the lighting module 20. In certain other embodiments, the heat tubes may transfer heat from the laser diode array 44 to a remote heat sink to promote efficient convective cooling.

The heat tubes may use phase change principles, with a working fluid that evaporates at the heat source (e.g., laser diode array 44) and condenses at a cooler region (e.g., heatsink). This process provides for rapid and efficient heat transfer away from the laser diode array 44 and lowers the operating temperature of the LDs 52. In another embodiment, the heat tubes may use a working fluid and wick structure to facilitate phase change heat transfer.

While use of heat tubes is described for use with a laser diode array, the heat tubes may be integrated with any illumination source to aid with cooling and to promote efficient operation.

In an embodiment, the lighting system includes a thermal management system for a laser diode array having heat tubes to transfer heat from the laser diode array to a heatsink, either directly integrated or located remotely. The heat tubes may use a working fluid and wick structure to facilitate phase change heat transfer.

In an embodiment, the lighting system includes an optical element for a laser diode source, having optical silicone materials with embedded micro-features to control the laser beam, and comolded sections with opaque or reflective surfaces. The optical element may be partitioned to enable beam steering and electronic beam control.

In other embodiments, a closed cooling system may be connected to the lighting module 20. Lighting module 20 may have openings within housing 40 into which cooling tubes or cooling pipes are inserted through the lighting module 20. The cooling tubes or pipes may be part of a closed cooling system including a pump and/or compressor connected to the cooling tubes. The cooling tubes of the closed cooling system may have cooling fluid circulating within the pipes and providing cooling for the lighting module 20. In certain embodiments, the closed cooling system may pass through a plurality of lighting modules (e.g., lighting module 20), while in other embodiments, each lighting module may have its own closed cooling system

Referring to FIGS. 7 and 8, To aid with cooling, a closed cooling system may pass into bore 82, through lighting module 20, and through mount 30, connecting a plurality of lighting modules and providing cooling for those lighting modules. In an alternate embodiment, fins 46 may be connected to the closed cooling system, acting as a heat sink.

In other embodiments, a fan system may be included to circulate air around the lighting modules, aiding the cooling fins 46 to dissipate heat from the lighting modules. The fan system may also provide air flow through bore 82 and through lighting module 20 to provide cooling. In still other embodiments, the fan system may be within in lighting module 20.

Referring to FIGS. 24-26, beams from each of the LDs 52 may be managed and controlled through a combination of optical features. A lens formed of optical silicone materials with embedded micro-features may be implemented in optical layer 248 to shape and direct the laser beam. Optical layer 248 may include micro-lenses 262 molded therein and in alignment with each LD 252 of asymmetric illumination source 244, with such micro-lenses 262 formed of optical silicone.

The optical silicone materials may include micro-features or micro-structures within the silicone material to control beam distribution, intensity, and uniformity. For example, in some embodiments, the micro-features or micro-structures may include sections with opaque and/or highly reflective surfaces, enhancing light control and minimizing unwanted scattering. The micro-features or micro-sections may be comolded.

Beam steering and control may be performed through the formation of partitioned optic sections. The optical element (e.g., the optical layer 248 and/or the micro-lenses 262) may be divided into multiple sections, each configured (e.g., shaped and dimensioned) to manipulate different parts of the beam. This configuration provides for dynamic beam steering and electronic beam control, promoting precise adjustments to the beam direction and shape.

Through beam shaping and steering light distribution optimization is promoted. The use of reflective and/or opaque surfaces within the optical elements (e.g., the optical layer 248 and/or the micro-lenses 262) minimizes light loss and maximizes output efficiency.

While beam shaping and steering here refers to sports field lighting, one skilled in the art would understand that such techniques are adaptable to various other applications requiring focused or distributed laser light.

One embodiment described herein is an illumination system, having a luminaire having an illumination source positioned in a housing and having a plurality of columns of laser diodes, each column of laser diodes is coupled to one of a corresponding plurality of independent electrical power pathways; a power supply enclosure independent from and positioned separately from the housing of the luminaire and enclosing a plurality of laser diode drivers, each of which is interconnected via wiring harness extending between the power supply enclosure and the housing to a corresponding one of the plurality of independent electrical power pathways in the housing so that each of the plurality of laser diode drivers can output an amount of power to each of the plurality of columns of laser diodes to cause each of the plurality of columns of laser diodes to illuminate; and a microprocessor positioned in the power supply enclosure and coupled to the plurality of laser diode drivers to set an amount of power that is output from each of the plurality of laser diode drivers to the corresponding one of the plurality of columns of laser diodes, where the microprocessor is configured to increase power output from any one of the plurality of laser diode drivers if power output from any other of the plurality of laser diode drivers decreases below the amount of power set by the microprocessor.

The illumination system of this embodiment further has a set of sensors coupled to the microprocessor for detecting a change in voltage, current, and power factor of the amount of power output to the plurality of columns of laser diodes or the amount of power used by the plurality of columns of laser diodes. The plurality of columns of laser diodes drivers of the illumination system has a single active power factor corrector coupled to a plurality of isolated DC/DC circuits, each of which is coupled to a corresponding one of the plurality of independent electrical power pathways.

The illumination system of this embodiment further has a second power supply enclosure having a second plurality of laser diode drivers, each of which is interconnected to a corresponding one of the one of a corresponding plurality of independent electrical power pathways so that each of the plurality of laser diode drivers outputs an amount of power to each of the plurality of columns of laser diodes to cause each of the plurality of columns of laser diodes to illuminate.

The illumination system of this embodiment, further has a switch that is moveable between a first position, where the first power supply enclosure is coupled to the plurality of independent electrical power pathways and the second power supply enclosure is isolated from the plurality of independent electrical power pathways, and a second position, where the first power supply enclosure is isolated from the plurality of independent electrical power pathways and the second power supply enclosure is coupled to the plurality of independent electrical power pathways. The second power supply enclosure of this illumination system includes a second microprocessor coupled to the second plurality of laser diode drivers to set the amount of power that is output from each of the second plurality of laser diode drivers to the plurality of columns of laser diodes, where the second microprocessor is configured to increase the amount of power output from any one of the second plurality of laser diode drivers if the amount of power output from any other of the second plurality of laser diode drivers decreases below the amount of power set by the second microprocessor.

The illumination system of this embodiment further has a master enclosure coupled to the first power supply enclosure, the second power supply enclosure, and the switch. The master enclosure of illumination system has a controller in communication with the first microprocessor of the first power supply enclosure and the second microprocessor of the second power supply enclosure. The controller of the illumination system is programmed to send a first command to the first microprocessor of the first power supply enclosure to set the amount of power output by the first plurality of power drivers and to send a second command to set the amount of power output by the second plurality of power drivers. The controller is further programmed to send the first command and the second command in response to a remote command received wirelessly from a remote host.

The illumination system of this embodiment further has a thermal management system for the plurality of columns of laser diodes having heat tubes connected to a heatsink. The heat tubes enclose a working fluid and a wick structure to facilitate phase change heat transfer.

The illumination system of this embodiment further has an optical element for a laser diode source, having optical silicone materials with embedded micro-features configured to control a laser beam and comolded sections having surfaces selected from a group consisting of opaque and reflective. The optical element of this illumination system is partitioned.

Another embodiment described herein is an asymmetrically controllable lighting system having a housing extending along a longitudinal axis and having an elongated opening; an illumination source positioned in the elongated opening of the housing and having a plurality of columns of laser diodes, each of which is coupled to one of a corresponding plurality of independent electrical power pathways; and a coupler positioned at one end of the longitudinal axis of the housing and having a plurality of electrical contacts interconnected to plurality of columns of laser diodes via each of the independent electrical power pathways. The plurality of columns of laser diodes extends along the longitudinal axis and perpendicular to the longitudinal axis.

The asymmetrically controllable lighting system of this embodiment further has an enclosure positioned remotely from the housing and including a plurality of laser diode drivers interconnected to the plurality of columns of laser diodes by a wiring harness coupled to the plurality of electrical contacts. Each of the plurality of laser diode drivers is configured to control the amount of illumination output by a corresponding one of plurality of columns of laser diodes using one of the independent electrical power pathways. Each of the plurality of laser diode drivers includes a local microprocessor responsive to an external command to set the amount of illumination output by the corresponding independently controllable column of laser diodes.

The asymmetrically controllable lighting system of this embodiment further has a central microprocessor having a communication interface programmed to be in wireless communication with a remote host. The central microprocessor is programmed to receive a wireless instruction from the remote host regarding the amount of illumination to be output by one of the plurality of columns of laser diodes and to send a corresponding digital command to cause the local microprocessor of the corresponding laser diode driver for the one of the plurality of columns of laser diodes to cause that laser diode driver to set the amount of illumination output by the one of the columns of laser diodes.

The asymmetrically controllable lighting system of this embodiment further has a thermal management system for the plurality of columns of laser diodes having heat tubes connected to a heatsink. The heat tubes enclose a working fluid and a wick structure to facilitate phase change heat transfer.

The asymmetrically controllable lighting system of this embodiment further has an optical element for a laser diode source, having optical silicone materials with embedded micro-features configured to control a laser beam and comolded sections having surfaces selected from a group consisting of opaque and reflective. The optical element is partitioned.

Another embodiment described herein is a lighting system having a luminaire having housing extending along a longitudinal axis and an illumination source positioned in an elongated opening of the housing, where the illumination source includes a plurality of columns of laser diodes, the plurality of columns extending longitudinally and perpendicular to the longitudinal axis; a core enclosure positioned remotely from the luminaire and having a plurality of laser diode drivers, each of which is interconnected to a corresponding one of the columns of laser diodes by a wiring harness extending therebetween, and a microprocessor coupled to the plurality of laser diode drivers and configured to set an amount of power output by the laser diode drivers to the columns of laser diodes, where the core enclosure is configured to convert power from an alternating current source into direct current powering the plurality of laser diode drivers; and a master enclosure having a controller in communication with the microprocessor of the core enclosure, where the controller commands the microprocessor of the core enclosure to control the amount of power output by the laser diode drivers. The power supply has a core enclosure having a plurality of laser diode drivers, each of which is associated with a corresponding one of the columns of laser diodes. The core enclosure has a microprocessor coupled to the plurality of laser diode drivers and configured to set an amount of power output by the laser diode drivers to the columns of laser diodes. The power supply comprises a master enclosure having a controller in communication with the microprocessor of the core enclosure. The controller commands the microprocessor of the core enclosure to control the amount of power output by the laser diode drivers based on the status of the lighting system. The core enclosure is mounted to a base of a support pole having a top on which the luminaire is mounted. The master enclosure is mounted to the base of the support pole proximately to the core enclosure. The core enclosure and the master enclosure are mounted to a back plane comprising a heat sink.

The lighting system of this embodiment further has a second luminaire and a second core enclosure having a second plurality of laser diode drivers interconnected to the second luminaire. The second core enclosure is interconnected to and responsive to the master enclosure to control an amount of power output by the second plurality of laser diode drivers. The first core enclosure, the second core enclosure, and the master enclosure are mounted to a back plane comprising a heat sink.

The lighting system of this embodiment further has a thermal management system for the plurality of columns of laser diodes having heat tubes connected to a heatsink. The heat tubes enclose a working fluid and a wick structure to facilitate phase change heat transfer.

The lighting system of this embodiment further has an optical element for a laser diode source, having optical silicone materials with embedded micro-features configured to control a laser beam and comolded sections having surfaces selected from a group consisting of opaque and reflective. The optical element is partitioned.

As described above, the present invention may be a system, a method, and/or a computer program associated therewith and is described herein with reference to flowcharts and block diagrams of methods and systems. The flowchart and block diagrams illustrate the architecture, functionality, and operation of possible implementations of systems, methods, and computer programs of the present invention. It should be understood that each block of the flowcharts and block diagrams can be implemented by computer readable program instructions in software, firmware, or dedicated analog or digital circuits. These computer readable program instructions may be implemented on the processor of a general purpose computer, a special purpose computer, or other programmable data processing apparatus to produce a machine that implements a part or all of any of the blocks in the flowcharts and block diagrams. Each block in the flowchart or block diagrams may represent a module, segment, or portion of instructions, which comprises one or more executable instructions for implementing the specified logical functions. It should also be noted that each block of the block diagrams and flowchart illustrations, or combinations of blocks in the block diagrams and flowcharts, can be implemented by special purpose hardware-based systems that perform the specified functions or acts or carry out combinations of special purpose hardware and computer instructions.

What is claimed is:

1. An illumination system, comprising:
a luminaire having an illumination source positioned in a housing and having a plurality of columns of laser diodes, each column of laser diodes is coupled to one of a corresponding plurality of independent electrical power pathways;
a power supply enclosure independent from and positioned separately from the housing of the luminaire and enclosing a plurality of laser diode drivers, each of which is interconnected via wiring harness extending between the power supply enclosure and the housing to a corresponding one of the plurality of independent electrical power pathways in the housing so that each of the plurality of laser diode drivers can output an amount of power to each of the plurality of columns of laser diodes to cause each of the plurality of columns of laser diodes to illuminate; and
a microprocessor positioned in the power supply enclosure and coupled to the plurality of laser diode drivers to set an amount of power that is output from each of the plurality of laser diode drivers to the corresponding one of the plurality of columns of laser diodes, wherein the microprocessor is configured to increase power output from any one of the plurality of laser diode drivers if power output from any other of the plurality of laser diode drivers decreases below the amount of power set by the microprocessor.

2. The illumination system of claim 1, further comprising a set of sensors coupled to the microprocessor for detecting a change in voltage, current, and power factor of the amount of power output to the plurality of columns of laser diodes or the amount of power used by the plurality of columns of laser diodes.

3. The illumination system of claim 2, wherein the plurality of columns of laser diodes drivers comprises a single active power factor corrector coupled to a plurality of isolated DC/DC circuits, each of which is coupled to a corresponding one of the plurality of independent electrical power pathways.

4. The illumination system of claim 3, further comprising a second power supply enclosure having a second plurality of laser diode drivers, each of which is interconnected to a corresponding one of the one of a corresponding plurality of independent electrical power pathways so that each of the plurality of laser diode drivers outputs an amount of power to each of the plurality of columns of laser diodes to cause each of the plurality of columns of laser diodes to illuminate.

5. The illumination system of claim 4, further comprising a switch that is moveable between a first position, where the first power supply enclosure is coupled to the plurality of independent electrical power pathways and the second power supply enclosure is isolated from the plurality of independent electrical power pathways, and a second position, where the first power supply enclosure is isolated from the plurality of independent electrical power pathways and the second power supply enclosure is coupled to the plurality of independent electrical power pathways.

6. The illumination system of claim 5, wherein the second power supply enclosure includes a second microprocessor coupled to the second plurality of laser diode drivers to set the amount of power that is output from each of the second plurality of laser diode drivers to the plurality of columns of laser diodes, wherein the second microprocessor is configured to increase the amount of power output from any one of the second plurality of laser diode drivers if the amount of power output from any other of the second plurality of laser diode drivers decreases below the amount of power set by the second microprocessor.

7. The illumination system of claim 6, further comprising a master enclosure coupled to the first power supply enclosure, the second power supply enclosure, and the switch.

8. The illumination system of claim 7, wherein the master enclosure comprises a controller in communication with the first microprocessor of the first power supply enclosure and the second microprocessor of the second power supply enclosure.

9. The illumination system of claim 8, wherein the controller is programmed to send a first command to the first microprocessor of the first power supply enclosure to set the amount of power output by the first plurality of power drivers and to send a second command to set the amount of power output by the second plurality of power drivers.

10. The illumination system of claim 8, the controller is programmed to send the first command and the second command in response to a remote command received wirelessly from a remote host.

11. The illumination system of claim 1, further comprising a thermal management system for the plurality of columns of laser diodes comprising heat tubes connected to a heatsink.

12. The illumination system of claim 11, wherein the heat tubes enclose a working fluid and a wick structure to facilitate phase change heat transfer.

13. The illumination system of claim 1 further comprising an optical element for a laser diode source, comprising optical silicone materials with embedded micro-features configured to control a laser beam and comolded sections having surfaces selected from a group consisting of opaque and reflective.

14. The illumination system of claim 13, wherein the optical element is partitioned.
